(19) United States
(12) Patent Application Publication
(10) Pub. No.: US 2017/0162772 A1
(43) Pub. Date: Jun. 8, 2017

(54) HEAT-DISSIPATION DEVICE OF LED

(71) Applicant: Yixing ZHANG, Beijing (CN)

(72) Inventor: Yixing ZHANG, Beijing (CN)

(21) Appl. No.: 15/320,837

(22) PCT Filed: Jul. 3, 2015
(86) PCT No.: PCT/CN2015/083294

§ 371 Date: Dec. 21, 2016

(30) Foreign Application Priority Data
Jul. 4, 2014 (CN) 201410317415.1

(51) Int. Cl. H01L 33/64

(52) U.S. Cl. CPC H01L 33/648

(57) ABSTRACT

Disclosed is a heat-dissipation device of an LED. The device comprises one or a plurality of heat conducting material silks; a heat-dissipation housing of an LED chip is contacted with one end of the heat conducting material silks through heat conducting materials or in a direct manner, in order to transmit the heat to the heat conducting material silks and heat the surrounding air through the heat conducting material silks; the heat conducting material silks are arranged in an air flowing pipeline, and the heat is taken away by the flowing air; the pipeline is made of insulation materials. The weight and size of the heat-dissipation device of the LED can be reduced exponentially under the condition that a proper working temperature for the LED chip is ensured, and the ground insulation of the whole heat-dissipation device can be ensured.

### TECHNICAL FIELD

The present invention belongs to the field of lighting electrical appliance, and specifically relates to a heat-dissipation device of an LED (Light Emitting Diode).

### TECHNICAL BACKGROUND

As green lighting, the LED has a series of prominent advantages. The LED lighting industry is in a phase of explosive growth currently.

As we see, although the LED has higher luminous efficiency than other light sources, more than half of energy obtained by the LED from a power supply is still used for heating. For the LED, a small LED chip always generates a lot of heat while emitting light, and the heat will directly influence the normal operation of the LED.

With the increase of the LED power, in order to increase the heat-dissipation surface area of a radiator, the present radiator is increasingly large and heavy but with little effect. Therefore, the heat-dissipation problem of the LED has been a problem that must be preferentially considered.

### SUMMARY

An aim of the present invention is to provide a heat-dissipation device of an LED. The weight and size of the heat-dissipation device of the LED can be reduced exponentially under the condition that a proper working temperature of the LED chip is ensured, and the ground insulation of the whole heat-dissipation device can also be ensured.

The present invention provides a heat-dissipation device of an LED. The device includes a large number of cylinders made of a heat conducting material. The diameters of the cylinders of the heat conducting material are less than 2 mm, and the minimum diameter is more than 0.01 mm; a heat-dissipation housing of an LED chip is contacted with one end of the cylinders made of the heat conducting material through the heat conducting material or in a direct manner, in order to heat the air around the cylinders, and the heat is taken away by the flowing air.

In the heat-dissipation device of the LED provided by the present invention, the diameters of the cylinders of the heat conducting material are less than 0.3 mm, so that the cylinders made of the heat conducting material form one or a plurality of heat conducting material wires; the heat-dissipation housing of the LED chip is contacted with one end of the heat conducting material wires through the heat conducting material or in a direct manner, in order to transmit the heat to the heat conducting material wires and heat the air around the heat conducting material wires; and the heat is taken away by the flowing air.

Further, the heat-dissipation housing of the LED chip can be directly fused with one end of the heat conducting material wires into a whole; the LED chip directly heats the air around the heat conducting material wires through the heat conducting material wires on the heat-dissipation housing thereof, and the heat is taken away by the flowing air.

Herein, the heat conducting material may be copper; the cylinders of the heat conducting material are copper cylinders, and the heat conducting material wires are copper wires.

The surfaces of the cylinders of the heat conducting material or the heat conducting material wires can be covered by a protective layer for preventing the cylinders of the heat conducting material or the heat conducting material wires from being oxidized, corroded or polluted.

Specifically, the protective layer covering the surfaces can be a silver plating, the cylinders of the heat conducting material, covered by the protective layer on the surfaces, are silvered copper cylinders, and the heat conducting material wires covered by the protective layer on the surfaces are silvered copper wires.

In the heat-dissipation device of the LED provided by the present invention, the cylinders of the heat conducting material or the heat conducting material wires are arranged in an air flowing pipeline; a blower is connected into the pipeline, and air is circulated by means of the blower to take away heat.

The heat-dissipation device of the LED provided by the present invention may not be connected with the blower, while the cylinders of the heat conducting material or the heat conducting material wires are arranged in an air-flowing pipeline of which the outlet and the inlet have a certain height difference, air becomes light by means of heating expansion to form a pressure difference between the outlet and the inlet, and the air circulation is promoted to take away heat.

Further, the device may also include a special air-flowing pipeline for storing the heated air; the outlet and the inlet of the special air-flowing pipeline have a certain height difference, air becomes light by means of heating expansion to form a pressure difference, and the air circulation is accelerated to take away heat.

The pipeline may be made of an insulation material, in order to ensure the ground insulation of the whole heat-dissipation device.

In the heat-dissipation device of the LED provided by the present invention, aluminum profiles which are usually large and heavy are changed into some metal wires arranged in the plastic pipeline, and the heat-dissipation effect of these metal wires is not hard to see through the following simple calculation. As we know, for a cylinder having a radius of r and a height of h, its volume is as follows:

V=πr²h

its lateral area is as follows:

S=2πrh

Thus, for the cylinder with the same volume, the area of the cylindrical surface is inversely proportional to the radius. In this case, the surface area of a copper wire having the diameter of 0.1 m is 100 times the lateral surface of a copper cylinder having the same volume and the diameter of 1 cm.

Accordingly, a sufficient heat-dissipation area can be obtained with only a small amount of copper wires. In this case, the weight and size of the heat-dissipation device of the LED can be reduced exponentially under the condition that a proper working temperature of the LED chip is ensured, and the ground insulation of the whole heat-dissipation device can also be ensured. This is a fundamental change for the heat-dissipation device of the LED.

### BRIEF DESCRIPTION OF THE DRAWINGS

FIG. 1 shows an LED chip and a plurality of copper wires welded on a heat-dissipation housing of the LED chip in the present invention.

FIG. 2 is a schematic diagram of a heat-dissipation device of an LED.

### DETAILED DESCRIPTION OF THE PREFERRED EMBODIMENT

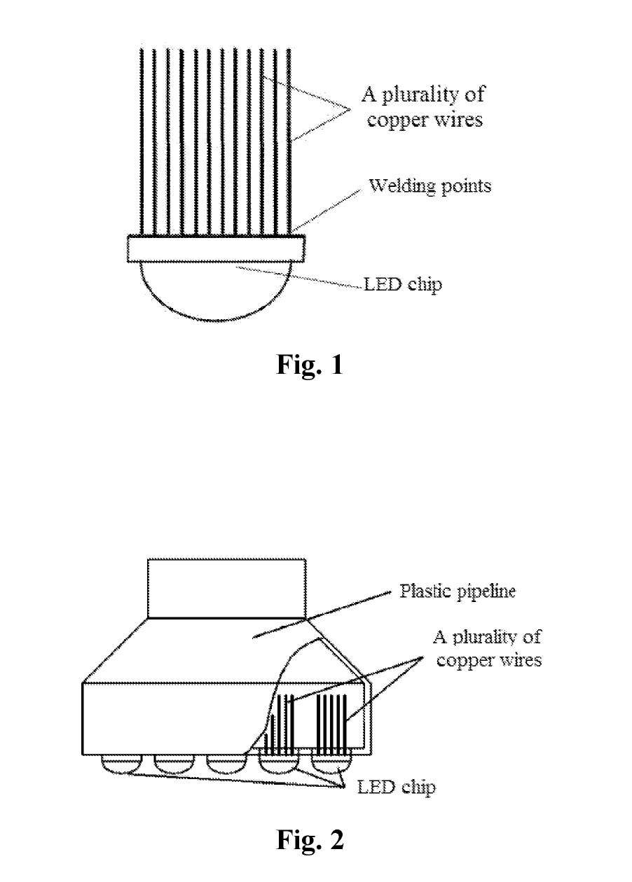

As shown in FIG. 1, as a beam of heat conducting material wires, a plurality of copper wires are directly welded on a heat-dissipation housing of an LED chip. The heat-dissipation housing transmits heat to the copper wires, in order to heat the air around the copper wires; and the heat is taken away by the flowing air.

The surfaces of the copper wires are covered by a protective layer for preventing the cylinders of the heat conducting material from being oxidized, corroded or polluted.

The heat-dissipation housing of the LED chip can be directly fused with one end of the copper wires into a whole.

As shown in FIG. 2, a plurality of LED chips welded with a plurality of copper wires are integrated together, and are properly arranged in an air-flowing plastic pipeline.

The outlet and the inlet of the plastic pipeline have a certain height difference, air becomes light by means of heating expansion to further form a pressure difference, and air circulation is promoted to take away heat.

The pipeline is made of an insulation material, in order to ensure the ground insulation of the whole heat-dissipation device.

The LED chips are properly connected with each other and are connected to a proper driving power supply to form an LED lamp as we need.

In the heat-dissipation device of the LED provided by the present invention, aluminum profiles which are usually large and heavy are changed into some metal wires arranged in the plastic pipeline, so that the weight and size of the heat-dissipation device of the LED can be reduced exponentially under the condition that a proper working temperature of the LED chip is ensured, and the ground insulation of the whole heat-dissipation device can also be ensured.

1. A heat-dissipation device of an LED, wherein the device comprises a large number of cylinders made of a heat conducting material, the diameters of the cylinders of the heat conducting material are more than 0.01 mm and less than 2 mm, a heat-dissipation housing of an LED chip is contacted with one end of the cylinders made of the heat conducting material through the heat conducting material or in a direct manner, in order to heat the air around the cylinders, and the heat is taken away by the flowing air.

2. The heat-dissipation device of the LED of claim 1, wherein the diameters of the cylinders of the heat conducting material are less than 0.3 mm, so that the cylinders made of the heat conducting material form one or a plurality of heat conducting material wires; the heat-dissipation housing of the LED chip is contacted with one end of the heat conducting material wires through the heat conducting material or in a direct manner, in order to transmit the heat to the heat conducting material wires and heat the air around the heat conducting material wires; and the heat is taken away by the flowing air.

3. The heat-dissipation device of the LED of claim 2, wherein the heat-dissipation housing of the LED chip is directly fused with one end of the heat conducting material wires into a whole; the LED chip directly heats the air around the heat conducting material wires through the heat conducting material wires on the heat-dissipation housing thereof, and the heat is taken away by the flowing air.

4. The heat-dissipation device of the LED of claim 1, wherein the heat conducting material is copper; the cylinders of the heat conducting material are copper cylinders, and the heat conducting material wires are copper wires.

5. The heat-dissipation device of the LED of claim 1, wherein the surfaces of the cylinders of the heat conducting material or the heat conducting material wires are covered by a protective layer for preventing the cylinders of the heat conducting material or the heat conducting material wires from being oxidized, corroded or polluted.

6. The heat-dissipation device of the LED of claim 5, wherein the protective layer covering the surfaces is a silver plating, the cylinders of the heat conducting material, covered by the protective layer on the surfaces, are silvered copper cylinders, and the heat conducting material wires covered by the protective layer on the surfaces are silvered copper wires.

7. The heat-dissipation device of the LED of claim 1, wherein the cylinders of the heat conducting material or the heat conducting material wires are arranged in an air-flowing pipeline; a blower is connected into the pipeline, and air is circulated by means of the blower to take away heat.

8. The heat-dissipation device of the LED of claim 1, wherein the cylinders of the heat conducting material or the heat conducting material wires are arranged in an air-flowing pipeline; the outlet and the inlet of the pipeline have a certain height difference, air becomes light by means of heating expansion to form a pressure difference between the outlet and the inlet, and air circulation is promoted to take away heat.

9. The heat-dissipation device of the LED of claim 8, wherein the device further comprises a special air-flowing pipeline for storing the heated air; the outlet and the inlet of the special air flowing pipeline have a certain height difference, air becomes light by means of heating expansion to form a pressure difference, and air circulation is accelerated to take away heat.

10. The heat-dissipation device of the LED of claim 7, wherein the pipeline is made of an insulation material, in order to ensure the ground insulation of the whole heat-dissipation device.
